(19) United States
(12) Patent Application Publication
(10) Pub. No.: US 2024/0178405 A1
(43) Pub. Date: May 30, 2024

(54) MACHINING APPARATUS FOR ELECTRODE PLATE AND MACHINING METHOD

(71) Applicant: Panasonic Intellectual Property Management co., Ltd., Osaka (JP)

(72) Inventors: Ryuta ABE, Osaka (JP); Tatsuya MASADA, Hyogo (JP); Masahide MARUYAMA, Osaka (JP)

(21) Appl. No.: 18/280,885

(22) PCT Filed: Jan. 18, 2022
(86) PCT No.: PCT/JP2022/001547

§ 371 Date: Sep. 7, 2023

(30) Foreign Application Priority Data
Mar. 9, 2021 (JP) 2021-036920

(51) Int. Cl. H01M 4/88; H01M 10/625; H05K 13/04

(52) U.S. Cl. CPC H01M 4/8875; H01M 4/8896; H01M 10/625; H05K 13/0417; H05K 13/0486; H01M 2220/20

(57) ABSTRACT

A machining apparatus for electrode plates includes: a machining part that forms an indent at the boundary between a tab portion and an unneeded portion in an area reserved for forming the tab portion of an electrode plate; and a removal part that detaches the unneeded portion from the electrode plate along the indent by applying force to the unneeded portion.

### TECHNICAL FIELD

The present disclosure relates to machining apparatuses for electrode plates and machining methods.

### BACKGROUND ART

In recent years, shipments of in-vehicle secondary batteries have been increasing with the spread of electric vehicles (EV), hybrid vehicles (HV), plug-in hybrid vehicles (PHV), and the like. In particular, shipments of lithium-ion secondary batteries are increasing. Further, secondary batteries are becoming widespread not only for in-vehicle use but also as a power source for portable terminals such as laptop computers.

A secondary battery as an example has a stacked electrode body in which a plurality of electrode plates are stacked and a battery case that houses the stacked electrode body and an electrolytic solution. Electrode plates have a structure in which an electrode active material layer is stacked on the surface of a current collector plate made of metal foil or the like. The electrode plates also have a tab portion protruding from one side of the current collector plate. Regarding such electrode plates, for example, Patent Literature 1 discloses an electrode production facility that continuously forms electrode plates by conveying an electrode material obtained by coating a strip-shaped current collector plate with an electrode active material and punching out the electrode material with a die roll cutter.

[Patent Literature 1] Japanese Unexamined Patent Application Publication No. 2017-196669

### SUMMARY OF INVENTION

### Technical Problem

In conventional electrode production facilities, tab portions are formed by punching out current collector plates with a die roll cutter. The present inventors have made a series of intensive studies on the method of forming tab portions and found that there is room for improvement in related-art formation methods in terms of improving the quality of electrode plates.

In this background, a purpose of the present disclosure is to provide a technology for improving the quality of electrode plates.

### Solution to Problem

One embodiment of the present disclosure relates to a machining apparatus for electrode plates. This machining apparatus includes: a machining part that forms an indent at the boundary between a tab portion and an unneeded portion in an area reserved for forming the tab portion of an electrode plate; and a removal part that detaches the unneeded portion from the electrode plate along the indent by applying force to the unneeded portion.

Another embodiment of the present disclosure relates to a machining method for electrode plates. This machining method includes: forming an indent at the boundary between a tab portion and an unneeded portion in an area reserved for forming the tab portion of an electrode plate; and detaching the unneeded portion from the electrode plate along the indent by applying force to the unneeded portion.

Optional combinations of the aforementioned constituting elements, and implementations of the present disclosure in the form of methods, apparatuses, and systems may also be practiced as additional modes of the present disclosure.

### Advantageous Effects of Invention

According to the present disclosure, the quality of electrode plates can be improved.

### BRIEF DESCRIPTION OF THE DRAWINGS

FIG. 1 is a perspective view of a machining apparatus for electrode plates according to an embodiment; and

FIGS. 2A, 2B and 2C are schematic diagrams for a grip part.

### DESCRIPTION OF EMBODIMENTS

Hereinafter, the present disclosure will be described based on a preferred embodiment with reference to the figures. The embodiments do not limit the present disclosure and are shown for illustrative purposes, and not all the features described in the embodiments and combinations thereof are necessarily essential to the present disclosure. The same or equivalent constituting elements, members, and processes illustrated in each drawing shall be denoted by the same reference numerals, and duplicative explanations will be omitted appropriately. The scales and shapes shown in the figures are defined for convenience's sake to make the explanation easy and shall not be interpreted limitatively unless otherwise specified. Terms like “first”, “second”, etc., used in the specification and claims do not indicate an order or importance by any means unless specified otherwise and are used to distinguish a certain feature from the others. Some of the components in each figure may be omitted if they are not important for explanation.

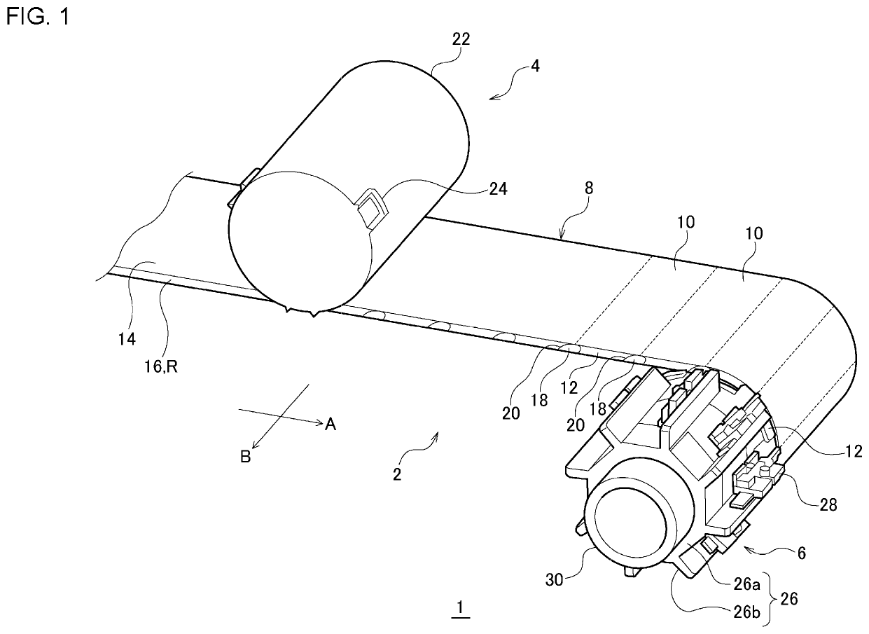

FIG. 1 is a perspective view of a machining apparatus 1 for electrode plates 10 according to an embodiment. The machining apparatus 1 for electrode plates 10 (hereinafter, abbreviated as “machining apparatus 1” as appropriate) includes a conveyance part 2, a machining part 4, and a removal part 6.

The conveyance part 2 conveys a plurality of electrode plates 10. As an example, the conveyance part 2 conveys a plurality of electrode plates 10 in a state of a continuous body 8 by means of a conveyance roll 30 or the like. The continuous body 8 is a strip of a plurality of electrode plates 10 connected together in a conveyance direction A of the electrode plates 10. The electrode plates 10 are eventually detached from each other. However, the position (time) at which each electrode plate 10 is detached is not particularly limited. A stacked electrode body can be obtained by alternately stacking individualized electrode plates 10 across a separator. The continuous body 8 may be used as a wound electrode body. The resulting stacked electrode body or wound electrode body can be used in rechargeable secondary batteries such as lithium-ion batteries, nickel-hydrogen batteries, nickel-cadmium batteries, and capacitors such as electric double-layer capacitors.

Each electrode plate 10 has a structure in which an electrode active material layer is stacked on a current collector plate. In the case of a standard lithium-ion secondary battery, the current collector plate is composed of aluminum foil or the like for a cathode and copper foil or the like for an anode. The electrode active material layer can be formed by applying an electrode mixture on the surface of the current collector using a known coating device, followed by drying and rolling. The electrode mixture is obtained by kneading and mixing materials such as an electrode active material, a binding material, and a conductive material into a dispersant and dispersing the materials uniformly. In the case of a standard lithium-ion secondary battery, the electrode active material is lithium cobalt oxide, lithium iron phosphate, or the like for the cathode and graphite or the like for the anode.

In a state after a machining process performed by the machining part 4 and the removal part 6 is applied to each electrode plate 10, each electrode plate 10 has a tab portion 12. The tab portion 12 protrudes from the current collector plate of the electrode plate 10 in the width direction B of the continuous body 8. The width direction B is a direction orthogonal to the conveyance direction A. The tab portion 12 is also referred to as a current collection tab and has a role of electrically connecting the current collector plate to the external terminal of the battery.

Each electrode plate 10 has an electrode active material coated part 14 and an electrode active material uncoated part 16. The electrode active material coated part 14 is arranged at least in the center in the width direction B. The coated part 14 corresponds to an electrode active material layer stacked on the current collector plate. The electrode active material uncoated part 16 is arranged at an end in the width direction B. Each electrode plate 10 shown in FIG. 1 has an uncoated part 16 at only one end in the width direction B. Alternatively, uncoated parts 16 may be provided at the respective ends. The uncoated part 16 is a part of the current collector plate that is exposed and corresponds to an area R reserved for forming the tab portion 12.

The machining part 4 forms an indent 20 at the boundary between the tab portion 12 and an unneeded portion 18 in the area R reserved for forming in each electrode plate 10. The unneeded portion 18 is a portion of the uncoated part 16 excluding the tab portion 12, which is detached from the electrode plate 10 by the removal part 6 and becomes waste material. The machining part 4 according to the present embodiment is arranged on the conveyance path of the electrode plates 10 and forms an indent 20 for each electrode plate 10 that is fed sequentially. The unneeded portion 18 may also be in contact with the coated part 14. In this case, an indent 20 is also formed at the boundary between the unneeded portion 18 and the coated part 14.

The machining part 4 according to the present embodiment has a die roll 22 that rotates synchronously with the conveyance of the electrode plates 10. The die roll 22 has a convex portion 24 corresponding to the boundary between the tab portion 12 and the unneeded portion 18, in other words, the contour of the unneeded portion 18 on the circumference of the roll. The die roll 22 rotates synchronously with the conveyance of the electrode plates 10, and the convex portion 24 is thereby pressed against the area R reserved for forming in each electrode plate 10 so as to form an indent 20. The depth of the indent 20 is, for example, about half the thickness of the current collector plate. As an example, the thickness of the current collector plate is about 10 μm, and the depth of the indent 20 is about 5 μm. The unneeded portion 18 is not completely divided by the indent 20, and a state where the unneeded portion 18 is connected to the electrode plate 10 is maintained.

The machining apparatus 1 may have a support (not shown) that supports the continuous body 8 at a position facing the machining part 4 across the continuous body 8. The support comprises, for example, a roll that rotates synchronously with the conveyance of the continuous body 8. When forming an indent 20 in an area R reserved for forming in each electrode plate 10, the indent 20 can be formed more reliably by sandwiching the electrode plate 10 between the convex portion 24 and the support. In addition, the accuracy of the depth of the indent 20 can be improved.

Each electrode plate 10 with an indent 20 formed by the machining part 4 is conveyed by the conveyance part 2 to the removal part 6. The removal part 6 detaches an unneeded portion 18 from the electrode plates 10 along the indent 20. The removal part 6 according to the present embodiment is arranged on the conveyance path of the electrode plates 10 and performs a process of detaching the unneeded portion 18 for each electrode plate 10 that is fed sequentially. The removal part 6 detaches an unneeded portion 18 from an electrode plate 10 by physically applying force to the unneeded portion 18. At this time, the indent 20 serves as a starting point for the separation of the electrode plate 10 and the unneeded portion 18. In other words, when the removal part 6 applies force to the unneeded portion 18, a tear occurs in the indent 20, and the unneeded portion 18 is separated from the electrode plate 10 when the tear spreads throughout the indent 20. This forms a tab portion 12.

The removal part 6 has a support 26 and a plurality of grip parts 28. The support 26 is a member that supports the plurality of grip parts 28 and has an annular part 26a and a plurality of bases 26b. The annular part 26a is coaxially arranged with the conveyance roll 30. As an example, the conveyance roll 30 is fixed and supports the rotation of the annular part 26a. The annular part 26a supports the continuous body 8 on the circumference thereof and rotates synchronously with the conveyance of the continuous body 8. Therefore, the annular part 26a according to the present embodiment constitutes a part of the conveyance part 2. A plurality of bases 26b are arranged at predetermined intervals in the circumferential direction of the annular part 26a. Each base 26b has a flat plate-like shape and projects radially from the circumference of the annular part 26a. Each base 26b is oriented such that a main surface thereof faces the circumferential direction of the annular part 26a.

On each base 26b, one grip part 28 is slidably installed in the width direction B. The grip part 28 can grip an unneeded portion 18 and can advance and retract with respect to an electrode plate 10. The grip part 28 can advance toward the electrode plate 10 to grip the unneeded portion 18, and then retract from the electrode plate 10 in this state so as to thereby pull the unneeded portion 18 and detach the unneeded portion 18 from the electrode plate 10.

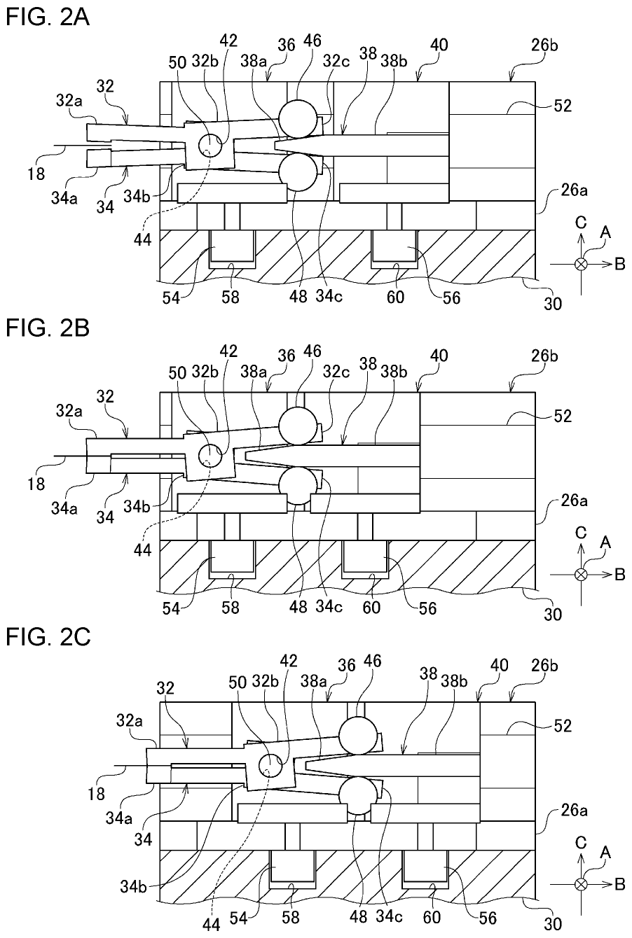

FIGS. 2A to 2C are schematic diagrams for the grip part 28. FIG. 2A shows the grip part 28 in a state of being in an advancing posture before gripping the unneeded portion 18. FIG. 2B shows the grip part 28 in a state of being in an advancing posture and gripping the unneeded portion 18. FIG. 2C shows the grip part 28 in a state of being in a retracting posture. In FIGS. 2A to 2C, the grip part 28 is illustrated being arranged side by side with the electrode plate 10. The illustration of the electrode plate 10 is omitted.

The grip part 28 has a first bowl 32, a second bowl 34, a first support 36, a wedge part 38, and a second support 40. The first bowl 32 and the second bowl 34 are each roughly rod-shaped and extend in the width direction B. The first bowl 32 and the second bowl 34 are aligned in the thickness direction C of the electrode plate 10 (orthogonal to the conveyance direction A and the width direction B).

The first bowl 32 has a first distal end 32a, a first middle portion 32b, and a first rear end 32c. In the width direction B, the first distal end 32a is arranged on the side closer to the electrode plate 10, the first rear end 32c is arranged on the side farther from the electrode plate 10, and the first middle portion 32b is arranged between the first distal end 32a and the first rear end 32c. The second bowl 34 has a second distal end 34a, a second middle portion 34b, and a second rear end 34c. In the width direction B, the second distal end 34a is arranged on the side closer to the electrode plate 10, the second rear end 34c is arranged on the side farther from the electrode plate 10, and the second middle portion 34b is arranged between the second distal end 34a and the second rear end 34c.

The first distal end 32a and the second distal end 34a face each other in the thickness direction C. In other words, the first distal end 32a and the second distal end 34a overlap each other in the thickness direction C. The first middle portion 32b has a first through hole 42 that penetrates the first middle portion 32b in the conveyance direction A. The second middle portion 34b has a second through hole 44 that penetrates the second middle portion 34b in the conveyance direction A. The first through hole 42 and the second through hole 44 overlap each other in the conveyance direction A. A first roll 46 is rotatably provided at the first rear end 32c. A second roll 48 is rotatably provided at the second rear end 34c. The first roll 46 and the second roll 48 face each other in the thickness direction C, and the respective rotation axes extend in the conveyance direction A.

The first bowl 32 and the second bowl 34 are supported by the first support 36. The first support 36 has a support shaft 50 extending in the conveyance direction A. The support shaft 50 is inserted into the first through hole 42. Thereby, the first bowl 32 is rotatably supported around the support shaft 50. Further, the support shaft 50 is inserted into the second through hole 44. Thereby, the second bowl 34 is rotatably supported around the support shaft 50. When the first bowl 32 and the second bowl 34 are rotated in a direction in which the first distal end 32a and the second distal end 34a approach each other, the first rear end 32c and the second rear end 34c become separated from each other. Conversely, when the first bowl 32 and the second bowl 34 are rotated in a direction in which the first distal end 32a and the second distal end 34a become separated from each other, the first rear end 32c and the second rear end 34c approach each other.

As an example, the first bowl 32 and the second bowl 34 are biased by a biasing member such as a spring (not shown) in a direction in which the first distal end 32a and the second distal end 34a are separated from each other and the first rear end 32c and the second rear end 34c approach each other.

The wedge part 38 is long in the width direction B and is arranged on a side farther from the electrode plate 10 than the first bowl 32 and the second bowl 34. The wedge part 38 has a tapered portion 38a at the end facing the first bowl 32 and the second bowl 34, which gradually decreases in size in the thickness direction C toward the tip. A portion of the tapered portion 38a is adjusted in size in the thickness direction C such that a gap larger than the thickness of the unneeded portion 18 is formed between the first distal end 32a and the second distal end 34a when the portion is pinched by the first roll 46 and the second roll 48. A body portion 38b excluding the tapered portion 38a of the wedge part 38 is adjusted in size in the direction of thickness C such that a gap equal to or less than the thickness of the unneeded portion 18 is formed or a gap disappears between the first distal end 32a and the second distal end 34a when the portion is pinched by the first roll 46 and the second roll 48.

The wedge part 38 is supported by the second support 40. While being supported by the second support 40, the wedge part 38 is arranged between the first roll 46 and the second roll 48. The second support 40 is arranged on a side farther from the electrode plate 10 than the first support 36. The first support 36 and the second support 40 are slidably fit to a rail 52 provided on a base 26b. The rail 52 extends in the width direction B. The first support 36 and the second support 40 can slide along the rail 52 while maintaining a distance from each other by a publicly-known sliding mechanism. This allows the first and second bowls 32 and 34 and the wedge part 38 to be advanced or retracted with respect to the electrode plate 10 while maintaining a distance from each other. Further, the first and second supports 36 and 40 can be displaced relatively along the rail 52. This allows the wedge part 38 to slide in the width direction B between the first roll 46 and the second roll 48.

As an example, the first support 36 and the second support 40 can be slid by a publicly-known cam mechanism. More specifically, a first cam follower 54 is provided on the first support 36. Further, a second cam follower 56 is provided on the second support 40. A first cam 58 and a second cam 60 are provided on the circumference of the conveyance roll 30. Therefore, the conveyance roll 30 according to the present embodiment constitutes a part of the removal part 6. The first cam follower 54 slidably engages the first cam 58, and the second cam follower 56 slidably engages the second cam 60. The first cam 58 and the second cam 60 are each provided over the entire circumference of the conveyance roll 30. Further, the distance of the first cam 58 and the second cam 60 from the continuous body 8 is adjusted such that the first support 36 and the second support 40 approach or become separated from the continuous body 8 when the first support 36 and the second support 40 are displaced in the circumferential direction of the conveyance roll 30.

As the support 26 rotates with respect to the conveyance roll 30, the first cam follower 54 moves along the first cam 58. This causes the first support 36 to slide in the width direction B. Further, as the support 26 rotates with respect to the conveyance roll 30, the second cam follower 56 moves along the second cam 60. This causes the second support 40 to slide in the width direction B. As the first support 36 and the second support 40 slide synchronously, the first and second bowls 32 and 34 and the wedge part 38 advance and retract with respect to the electrode plate 10 while maintaining the distance from each other. Sliding only the second support 40 or making the amount of sliding of the second support 40 larger than the amount of sliding of the first support 36 causes the wedge part 38 to be displaced with respect to the first bowl 32 and the second bowl 34.

Each grip part 28 is sequentially sent to the detachment position of the unneeded portion 18 by rotation of the support 26, and after reaching the detachment position, the grip part 28 moves away from the detachment position. In this process, each grip part 28 operates as follows. First, as shown in FIG. 2A, in the process of the grip part 28 approaching the detachment position of the unneeded part 18, the first support 36 and the second support 40 slide toward the electrode plate 10. In this state, the tapered portion 38a is interposed between the first roll 46 and the second roll 48. Accordingly, a gap is formed between the first distal end 32a and the second distal end 34a. The grip part 28 that has reached the detachment position takes an advancing posture with respect to the electrode plate 10, and the unneeded portion 18 enters the gap between the first distal end 32a and the second distal end 34a.

Then, as shown in FIG. 2B, the second support 40 is further displaced toward the electrode plate 10 while the first support 36 is stopped. This causes the tapered portion 38a to advance between the first roll 46 and the second roll 48. At this time, the first roll 46 and the second roll 48 are displaced in the direction of being separated from each other against the biasing force of the biasing member by being pushed by the tapered portion 38a. As a result, the first rear end 32c and the second rear end 34c are displaced in the direction of being separated from each other, and the first distal end 32a and the second distal end 34a are displaced in the direction of approaching each other. When the wedge part 38 is displaced to a position where the body portion 38b is pinched by the first roll 46 and the second roll 48, the unneeded portion 18 is gripped by the first distal end 32a and the second distal end 34a.

Then, as shown in FIG. 2C, in the process of the grip part 28 moving away from the detachment position of the unneeded portion 18, the first support 36 and the second support 40 slide in a direction of being separated from the electrode plate 10 while maintaining a distance from each other. As a result, the grip part 28 takes a retracting posture with respect to the electrode plate 10. At this time, the body portion 38b is interposed between the first roll 46 and the second roll 48. Therefore, a state is maintained where the unneeded portion 18 is gripped by the first distal end 32a and the second distal end 34a. As the grip part 28 is getting separated from the electrode plate 10 while gripping the unneeded portion 18, a tear is created in the indent 20 such that the unneeded portion 18 is detached from the electrode plate 10.

The grip part 28 gripping the unneeded portion 18 reaches a disposal position of the unneeded portion 18 by rotation of the conveyance roll 30. In the process of the grip part 28 approaching the disposal position, the second support 40 is displaced in a direction being separated from the first support 36. The second support 40 is displaced to a position where the tapered portion 38a is interposed between the first roll 46 and the second roll 48 or a position where the wedge part 38 is completely withdrawn. At this time, the first roll 46 and the second roll 48 are displaced in the direction of approaching each other by the biasing force of the biasing member. As a result, the first rear end 32c and the second rear end 34c are displaced in the direction of approaching each other, and the first distal end 32a and the second distal end 34a are displaced in the direction of being separated from each other. As a result, a gap is created between the first distal end 32a and the second distal end 34a so as to release the unneeded portion 18. The released unneeded portion 18 is removed from the grip part 28 at the disposal position due to falling under its own weight or by a suction mechanism.

In the present embodiment, the first bowl 32 and the second bowl 34 are opened and closed by the wedge part 38. Alternatively, the first bowl 32 and the second bowl 34 may be opened and closed by other mechanisms. The unneeded part 18 is gripped by the grip part 28 and torn from the electrode plate 10. Alternatively, the unneeded part 18 may be detached from the electrode plate 10 by another mechanism. For example, the removal part 6 may have a protruding portion that can advance and retract in a radial direction from the annular part 26a, and the unneeded portion 18 may be detached from the electrode plate 10 by pushing the unneeded portion 18 in the thickness direction C using this protruding portion. Further, the removal part 6 according to the present embodiment has a structure in which a plurality of grip parts 28 are supported by the support 26 in an annular shape. However, without limiting thereto, the plurality of grip parts 28 may be aligned in a straight line, for example.

As explained above, a machining apparatus 1 for electrode plates 10 according to the present embodiment comprises: a machining part 4 that forms an indent 20 at the boundary between a tab portion 12 and an unneeded portion 18 in an area R reserved for forming the tab portion 12 of an electrode plate 10; and a removal part 6 that detaches the unneeded portion 18 from the electrode plate 10 along the indent 20 by applying force to the unneeded portion 18.

A possible method for forming a tab portion 12 on an electrode plate 10 is to use a die roll cutter to press and cut the electrode plate 10. However, in this case, vertical burrs are likely to occur on the edge of the electrode plate 10 due to friction between the electrode plate 10 and the cutting blade. Further, the cutting edge is prone to chipping and wear. Another possible method for forming a tab portion 12 on an electrode plate 10 is to apply laser processing to an area R reserved for forming the tab portion 12. However, in this case, it is not easy to accurately form the tab portion 12 due to the flapping of the electrode plate 10 during conveyance. Further, since spatter occurs when the electrode plate 10 is cut with a laser, it is necessary to provide a chamber or the like.

On the other hand, in the present embodiment, by placing an indent 20 at the boundary between the tab portion 12 and the unneeded portion 18 and applying force to the unneeded portion 18, the unneeded portion 18 is detached from the electrode plate 10 using the indent 20 as a starting point. This can reduce friction between the electrode plate 10 and the blade compared to a case where the electrode plate 10 is pressed and cut with a cutting blade. Therefore, it is possible to suppress the occurrence of burrs on the edge of the electrode plate 10. Blade chipping and wear can also be suppressed. Further, an indent 20 is formed by pressing a convex portion 24 against the electrode plate 10. Therefore, the indent 20 can be formed by pressing down the electrode plate 10 that flaps during conveyance. Further, the flapping of the electrode plate 10 has substantially no effect on the operation of tearing the unneeded portion 18 starting from the indent 20. Therefore, the accuracy of forming a tab portion 12 can be more easily improved compared to laser processing. From the above, the quality of the electrode plate 10 can be improved according to the machining apparatus 1 according to the present embodiment.

The machining apparatus 1 according to the present embodiment includes a conveyance part 2 that conveys a plurality of electrode plates 10. Further, the machining part 4 and the removal part 6 are arranged on the conveyance path of the electrode plates 10 so as to form an indent 20 on each electrode plate 10 that is fed sequentially and detach an unneeded portion 18. This allows the throughput of the machining apparatus 1 to be increased.

The machining part 4 according to the present embodiment has a die roll 22 that has a convex portion 24 corresponding to the boundary between the tab portion 12 and the unneeded portion 18 on the circumference and rotates synchronously with the conveyance of the electrode plates 10. This enables the continuous formation of indents 20 on a plurality of electrode plates 10 with a simpler configuration.

Further, the removal part 6 according to the present embodiment has a grip part 28 that can advance and retract with respect to an electrode plate 10 and that grips an unneeded portion 18. This allows the unneeded portion 18 to be torn from the electrode plate 10 using the indent 20 as a starting point.

Described above is a detailed explanation on the embodiments of the present disclosure. The above-described embodiments merely show specific examples for carrying out the present disclosure. The details of the embodiments do not limit the technical scope of the present disclosure, and many design modifications such as change, addition, deletion, etc., of the constituent elements may be made without departing from the spirit of the present disclosure defined in the claims. New embodiments resulting from added design change will provide the advantages of the embodiments and variations that are combined. In the above-described embodiments, the details for which such design change is possible are emphasized with the notations “according to the embodiment”, “in the embodiment”, etc. However, design change is also allowed for those without such notations. Optional combinations of the above constituting elements are also valid as embodiments of the present disclosure. Hatching applied to a cross section of a drawing does not limit the material of an object to which the hatching is applied.

The embodiments may be defined by the items described in the following.

### [Item 1]

A machining apparatus (1) for electrode plates (10), including:
a machining part (4) that forms an indent (20) at the boundary between a tab portion (12) and an unneeded portion (18) in an area (R) reserved for forming the tab portion (12) of an electrode plate (10); and
a removal part (6) that detaches the unneeded portion (18) from the electrode plate (10) along the indent (20) by applying force to the unneeded portion (18).

### [Item 2]

The machining apparatus (1) for electrode plates (10) according to Item 1, including
a conveyance part (2) that conveys a plurality of electrode plates (10), wherein
the machining part (4) and the removal part (6) are arranged on a conveyance path of the electrode plates (10) so as to form an indent (20) on each electrode plate (10) that is fed sequentially and detach an unneeded portion (18).

### [Item 3]

The machining apparatus (1) for electrode plates (10) according to Item 2, wherein
the machining part (4) has a die roll (22) that has a convex portion (24) corresponding to the boundary on the circumference and rotates synchronously with the conveyance of the electrode plates (10).

### [Item 4]

The machining apparatus (1) for electrode plates (10) according to any one of Items 1 through 3, wherein
the removal part (6) has a grip part (28) that can advance and retract with respect to an electrode plate (10) and that grips an unneeded portion (18).

### [Item 5]

A machining method for electrode plates (10), including:
forming an indent (20) at the boundary between a tab portion (12) and an unneeded portion (18) in an area (R) reserved for forming the tab portion (12) of an electrode plate (10); and
detaching the unneeded portion (18) from the electrode plate (10) along the indent (20) by applying force to the unneeded portion (18).

### INDUSTRIAL APPLICABILITY

The present disclosure can be used for machining apparatuses for electrode plates and machining methods.

### REFERENCE SIGNS LIST

1 machining apparatus, 2 conveyance part, 4 machining part, 6 removal part, 10 electrode plate, 12 tab portion, 18 unneeded portion, 20 indent, 22 die roll, 24 convex portion, 28 grip part, R area reserved for forming

1. A machining apparatus for electrode plates, comprising:
a machining part that forms an indent at the boundary between a tab portion and an unneeded portion in an area reserved for forming the tab portion of an electrode plate; and
a removal part that detaches the unneeded portion from the electrode plate along the indent by applying force to the unneeded portion.

2. The machining apparatus for electrode plates according to claim 1, comprising:
a conveyance part that conveys a plurality of electrode plates, wherein
the machining part and the removal part are arranged on a conveyance path of the electrode plates so as to form the indent on each electrode plate that is fed sequentially and detach the unneeded portion.

3. The machining apparatus for electrode plates according to claim 2, wherein
the machining part has a die roll that has a convex portion corresponding to the boundary on the circumference and rotates synchronously with the conveyance of the electrode plates.

4. The machining apparatus for electrode plates according to claim 1, wherein
the removal part has a grip part that can advance and retract with respect to the electrode plate and that grips the unneeded portion.

5. A machining method for electrode plates, comprising:
forming an indent at the boundary between a tab portion and an unneeded portion in an area reserved for forming the tab portion of an electrode plate; and
detaching the unneeded portion from the electrode plate along the indent by applying force to the unneeded portion.
